(19) United States
(12) Patent Application Publication
(10) Pub. No.: US 2024/0414901 A1
(43) Pub. Date: Dec. 12, 2024

(54) DISPLAY PANEL AND DISPLAY APPARATUS

(71) Applicant: Wuhan Tianma Microelectronics Co., Ltd., Wuhan (CN)

(72) Inventors: Fang WAN, Wuhan (CN); Yueji CHEN, Wuhan (CN); Jiang CHEN, Wuhan (CN); Kang YANG, Wuhan (CN)

(21) Appl. No.: 18/809,447

(22) Filed: Aug. 20, 2024

(30) Foreign Application Priority Data
Aug. 29, 2023 (CN) 202311110233.2

(51) Int. Cl. H05K 9/00

(52) U.S. Cl. CPC H05K 9/0067

(57) ABSTRACT

Embodiments of the present disclosure relate to the display field, and provide a display panel and a display apparatus, to improve an electrostatic protection capability of the display panel. The display panel includes a display substrate; a cover plate located on a side of the display substrate facing a light exit surface of the display panel; a first coating located on a side of the cover plate away from the display substrate; and a second coating at least partially located on a side of the cover plate adjacent to the display substrate, where surface resistance of the second coating is greater than surface resistance of the first coating.

### CROSS-REFERENCE TO RELATED APPLICATIONS

The present application claims priority to Chinese Patent Application No. 202311110233.2, filed on Aug. 29, 2023, the content of which is incorporated herein by reference in its entirety.

### TECHNICAL FIELD

The present disclosure relates to displays, and in particular, to a display panel and a display apparatus.

### BACKGROUND

At present, most cover plates of display panels are glass cover plates, but the glass cover plates are prone to generating electrostatic electricity under a friction condition and have a weak anti-electrostatic propagation capability. As a result, massive electrostatic charges generated by friction are further transmitted to an interior of the display panel through the cover plate, affecting an electrical characteristic of an electronic device inside the display panel and causing an electrical deviation to the electronic device.

For example, after the frictional electrostatic charges enter a gate insulating layer inside the panel, more defects are caused inside the gate insulating layer, which causes a threshold voltage of a transistor to be positively biased. As a result, a high current flows into a light-emitting element, and brightness of the light-emitting element is high, resulting in uneven display on the display panel.

### SUMMARY

In view of this, embodiments of the present disclosure provide a display panel and a display apparatus, to improve an electrostatic protection capability of the display panel.

According to an aspect, an embodiment of the present disclosure provides a display panel, including:
a display substrate;
a cover plate located on a side of the display substrate facing a light exit surface of the display panel;
a first coating located on a side of the cover plate away from the display substrate; and
a second coating at least partially located on a side of the cover plate adjacent to the display substrate, where a surface resistance of the second coating is greater than a surface resistance of the first coating.

According to another aspect, an embodiment of the present disclosure provides a display apparatus, including the foregoing display panel.

One of the foregoing technical solutions has following beneficial effects:

In a research process, the inventor finds that electrostatic protection coatings with different surface resistance have different electrostatic suppression effects. A coating with low surface resistance can quickly diffuse an electrostatic charge. This makes it easier and faster to dissipate the electrostatic charge in water vapor of air, preventing the electrostatic charge from being accumulated on a surface. A coating with high surface resistance can act as a high-resistance structure to block transmission of the electrostatic charge and weaken a transmission capability of the electrostatic charge.

By comprehensively considering the different electrostatic suppression effects of the coatings with different surface resistance, the embodiments of the present disclosure dispose a low-resistance first coating and a high-resistance second coating on outer and inner sides of a cover plate respectively. The first coating with low surface resistance is disposed on the outer side of the cover plate (a side adjacent to a light exit surface of a display panel). In this way, after electrostatic electricity is generated by friction, the first coating can be used to accelerate dissipation of the electrostatic charge, thereby reducing frictional electrostatic charges accumulated on an outer surface of the display panel. The second coating with high surface resistance is further disposed on the inner side of the cover plate (a side far away from the light exit surface of the display panel), to further block transmission of the frictional electrostatic charge to prevent the frictional electrostatic charge from further being transmitted to an interior of a display substrate after entering the cover plate.

Compared with a method of forming a single electrostatic protection layer only on one side of the cover plate, the embodiments of the present disclosure simultaneously dispose the first and second coatings on the two sides of the cover plate to achieve different electrostatic protection effects, thereby reducing electrostatic charges accumulated on the outer side of the cover plate and blocking electrostatic transmission on the inner side of the cover plate based on mutual cooperation between the first coating and the second coating. In this way, the electrostatic charges on the inner and outer sides of the cover plate are suppressed to a certain extent, thereby significantly improving an electrostatic protection capability of the display panel. In this way, frictional electrostatic charges transmitted to an interior of the display substrate can be significantly reduced, preventing the frictional electrostatic charges from affecting an electrical characteristic of an electronic device inside the display substrate, and effectively improving a phenomenon of uneven display on the display panel.

### BRIEF DESCRIPTION OF DRAWINGS

To describe the technical solutions in the embodiments of the present disclosure more clearly, the following briefly describes the accompanying drawings required to be used in the embodiments. Apparently, the accompanying drawings in the following description show merely some embodiments of the present disclosure, and a person of ordinary skill in the art may still derive other accompanying drawings from these accompanying drawings without creative efforts.

FIG. 1 is a schematic cross-sectional view of a display panel according to an embodiment of the present disclosure;

FIG. 2 is a schematic cross-sectional view of a display panel according to an embodiment of the present disclosure;

FIG. 3 is a schematic comparison diagram of electrostatic transmission according to an embodiment of the present disclosure;

FIG. 4 is another schematic cross-sectional view of a display panel according to an embodiment of the present disclosure;

FIG. 5 is a top view of a cover plate, an ink layer, and a second coating according to an embodiment of the present disclosure;

FIG. 6 is a cutaway view along line A1-A2 shown in FIG. 5;

FIG. 7 is another cutaway view along line A1-A2 shown in FIG. 5;

FIG. 8 is a top view of a cover plate and a second coating according to an embodiment of the present disclosure;

FIG. 9 is another top view of a cover plate and a second coating according to an embodiment of the present disclosure;

FIG. 10 is a cutaway view along line B1-B2 shown in FIG. 9;

FIG. 11 is still another top view of a cover plate and a second coating according to an embodiment of the present disclosure;

FIG. 12 is a cutaway view along line C1-C2 shown in FIG. 11;

FIG. 13 is yet another top view of a cover plate and a second coating according to an embodiment of the present disclosure;

FIG. 14 is a cutaway view along line D1-D2 shown in FIG. 13;

FIG. 15 is still another schematic cross-sectional view of a display panel according to an embodiment of the present disclosure;

FIG. 16 is still another schematic cross-sectional view of a display panel according to an embodiment of the present disclosure;

FIG. 17 is still another schematic cross-sectional view of a display panel according to an embodiment of the present disclosure;

FIG. 18 is still another schematic cross-sectional view of a display panel according to an embodiment of the present disclosure;

FIG. 19 is still another schematic cross-sectional view of a display panel according to an embodiment of the present disclosure; and

FIG. 20 is a schematic structural diagram of a display apparatus according to an embodiment of the present disclosure.

### DETAILED DESCRIPTION

For the sake of a better understanding of the technical solutions of the present disclosure, the embodiments of the present disclosure are described in detail below with reference to the accompanying drawings.

It should be noted that the embodiments in the following descriptions are merely some rather than all of the embodiments of the present disclosure. All other embodiments obtained by a person of ordinary skill in the art on the basis of the embodiments of the present disclosure without creative efforts shall fall within the protection scope of the present disclosure.

Terms used in the embodiments of the present disclosure are only for the purpose of describing specific embodiments, and are not intended to limit the present disclosure. Unless otherwise specified in the context, words, such as “a”, “the”, and “this”, in a singular form in the embodiments of the present disclosure and the appended claims include plural forms.

It should be understood that the term “and/or” in this specification merely describes associations between associated objects, and it indicates three types of relationships. For example, A and/or B may indicate that A exists alone, A and B coexist, or B exists alone. In addition, the character “/” in this specification generally indicates that the associated objects are in an “or” relationship.

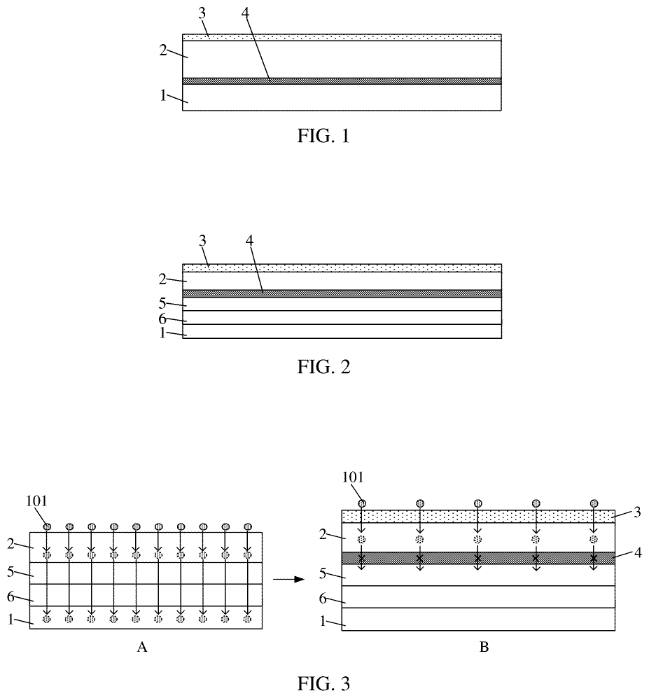

The embodiments of the present disclosure provide a display panel. FIG. 1 is a schematic cross-sectional view of a display panel according to an embodiment of the present disclosure. As shown in FIG. 1, the display panel includes a display substrate 1, a cover plate 2, a first coating 3, and a second coating 4. The cover plate 2 is located on a side of the display substrate 1 facing a light exit surface of the display panel, and may specifically be a glass cover plate. The first coating 3 is located on a side of the cover plate 2 away from the display substrate 1. The second coating 4 is at least partially located on a side of the cover plate 2 adjacent to the display substrate 1. Surface resistance of the second coating 4 is greater than surface resistance of the first coating 3, in other words, the first coating 3 is a low-resistance coating, and the second coating 4 is a high-resistance coating.

More specifically, in a setting method, as shown in FIG. 2 that is a schematic cross-sectional view of the display panel according to an embodiment of the present disclosure, the display panel further includes optically clear adhesive 5 and a polarizer 6, which are located between the display substrate 1 and the cover plate 2. The optically clear adhesive 5 is located between the polarizer 6 and the cover plate 2. The first coating 3 may be located on a surface of the cover plate 2 away from the optically clear adhesive 5, and the second coating 4 may be at least partially located between the cover plate 2 and the optically clear adhesive 5.

In a research process, the inventor finds that electrostatic protection coatings with different surface resistance have different electrostatic suppression effects. A coating with low surface resistance can quickly diffuse an electrostatic charge. This makes it easier and faster to dissipate the electrostatic charge in water vapor of air, preventing the electrostatic charge from being accumulated on a surface. A coating with high surface resistance can act as a high-resistance structure to block transmission of the electrostatic charge and weaken a transmission capability of the electrostatic charge.

By comprehensively considering the different electrostatic suppression effects of the coatings with different surface resistance, the embodiments of the present disclosure dispose the low-resistance first coating 3 and the high-resistance second coating 4 on outer and inner sides of the cover plate 2 respectively. The first coating 3 with low surface resistance is disposed on the outer side of the cover plate 2 (a side adjacent to the light exit surface of the display panel). In this way, after electrostatic electricity is generated by friction, the first coating 3 can be used to accelerate dissipation of the electrostatic charge, thereby reducing frictional electrostatic charges accumulated on an outer surface of the display panel. The second coating 4 with high surface resistance is further disposed on the inner side of the cover plate 2 (a side far away from the light exit surface of the display panel), to further block transmission of the frictional electrostatic charges to prevent the frictional electrostatic charges from further being transmitted to an interior of the display substrate 1 after entering the cover plate 2.

FIG. 3 is a schematic comparison diagram of electrostatic transmission according to an embodiment of the present disclosure. In FIG. 3, A schematically shows generation and transmission of the electrostatic electricity when the first coating 3 and the second coating 4 are not disposed on the two sides of the cover plate 2, while B schematically shows generation and transmission of the electrostatic electricity when the first coating 3 and the second coating 4 are disposed on the two sides of the cover plate 2. Referring to A, when the first coating 3 and the second coating 4 are not disposed, a large number of frictional electrostatic charges 101 are accumulated on the outer side of the cover plate 2, and further penetrate the interior of the display substrate 1 through the cover plate 2, the optically clear adhesive 5, and the polarizer 6. In the embodiments of the present disclosure, referring to B, after the first coating 3 and the second coating 4 are disposed on the two opposite sides of the cover plate 2, the accumulated frictional electrostatic charges 101 on the outer side of the cover plate 2 can be significantly reduced directly. In addition, even if the accumulated frictional electrostatic charges 101 enter the cover plate 2, the accumulated frictional electrostatic charges 101 are blocked by the second coating 4 on the inner side of the cover plate 2, and cannot be transmitted to the optically clear adhesive 5, thereby preventing the accumulated frictional electrostatic charges 101 from being transmitted to the interior of the display substrate 1.

Compared with a method of forming a single electrostatic protection layer only on one side of the cover plate 2, the embodiments of the present disclosure simultaneously dispose the first coating 3 and the second coating 4 on the two sides of the cover plate 2 to achieve different electrostatic protection effects, thereby reducing the electrostatic charges accumulated on the outer side of the cover plate 2 and blocking electrostatic transmission on the inner side of the cover plate 2 based on mutual cooperation between the first coating 3 and the second coating 4. In this way, the electrostatic charges on the inner and outer sides of the cover plate 2 are suppressed to a certain extent, thereby significantly improving an electrostatic protection capability of the display panel. In this way, the frictional electrostatic charges transmitted to the interior of the display substrate 1 can be significantly reduced, preventing the frictional electrostatic charges affecting an electrical characteristic of an electronic device inside the display substrate 1, and effectively improving a phenomenon of uneven display on the display panel.

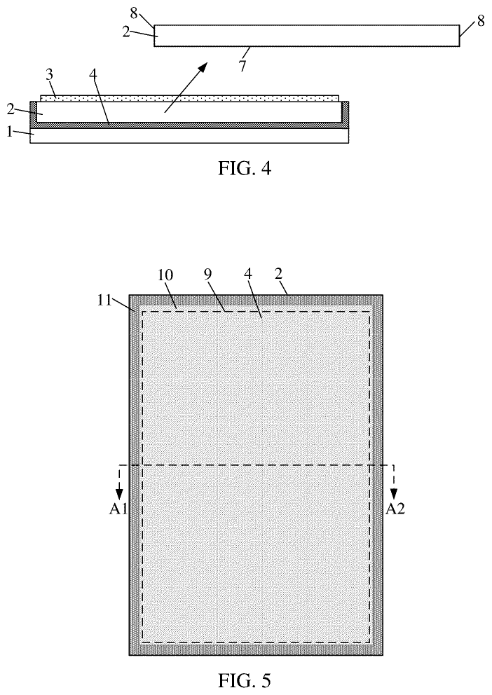

In a feasible implementation, as shown in FIG. 4 that is another schematic cross-sectional view of the display panel according to an embodiment of the present disclosure, the cover plate 2 includes a bottom surface 7 adjacent to the display substrate 1 and a sidewall 8 intersecting the bottom surface 7. The second coating 4 is located at the bottom surface 7 and a side of the sidewall 8. For example, the second coating 4 coats at least the sidewall 8 of the cover plate 2 in a thickness direction of the display panel, and an orthographic projection of the second coating 4 in the thickness direction of the display panel covers the bottom surface 7 of the cover plate 2.

In this setting method, the second coating 4 is located at both the bottom surface 7 and the side of the sidewall 8 on the cover plate 2. The second coating 4 can not only block inward transmission of a frictional electrostatic charge in the cover plate 2 at a bottom of the cover plate 2, but also prevent an external electrostatic charge from entering the cover plate 2 at the sidewall 8 of the cover plate 2 and block inward transmission of an electrostatic charge at the sidewall 8 of the cover plate 2. The second coating 4 of this structure can provide more comprehensive electrostatic protection for the cover plate 2, to greatly reduce electrostatic charges entering the interior of display substrate 1.

It should be additionally noted that the second coating 4 is disposed on the side of the sidewall 8 of the cover plate 2 in the embodiments of the present disclosure by comprehensively considering following points:

Firstly, side area of the display panel (which can be seen as area of the cover plate 2 on the sidewall 8) is much smaller than front area (which can be seen as area of the cover plate 2 on the bottom surface 7). Therefore, compared with a front surface, a side surface of the display panel has smaller friction area, and less frictional electro static charges are generated. Correspondingly, less electrostatic charges are accumulated on the side surface. If the first coating 3 is disposed on the side of the sidewall 8 of the cover plate 2 from a perspective of reducing frictional electrostatic charges accumulated on the side surface, few electrostatic charges are generated on the side surface. Therefore, the accumulated electrostatic charges are not significantly reduced. However, when the second coating 4 is disposed on the side of the sidewall 8 of the cover plate 2, the second coating 4 can wrap the cover plate 2 in a more comprehensive way. Both an electrostatic charge generated by friction on the side surface of the display panel and an electrostatic charge transmitted from another location inside the cover plate 2 to the side surface can be blocked by the second coating 4 on the sidewall 8, thereby preventing the electrostatic charges from being transmitted to an interior of the display panel. In this way, an overall electrostatic protection effect of the display panel is more significantly improved.

Moreover, when the second coating 4 is designed as the high-resistance coating, a high-resistance material is used, and the surface resistance of the second coating 4 can be further increased by thinning the second coating 4. Therefore, in a setting method, a film thickness of the second coating 4 is much smaller than a film thickness of the first coating 3. Therefore, the second coating 4 is disposed on the side of the sidewall 8 of the cover plate 2. This achieves effective electrostatic protection on the side surface of the display panel, without significantly affecting a size of a display module.

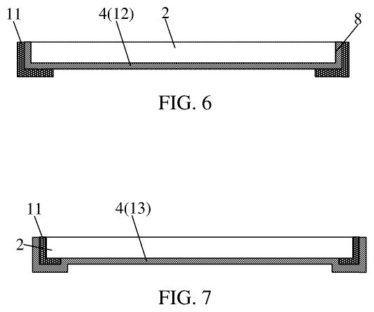

In a feasible implementation, as shown in FIG. 5 and FIG. 6, the display panel includes a display region 9 and a bezel region 10. FIG. 5 is a top view of the cover plate 2, an ink layer 11, and the second coating 4 according to an embodiment of the present disclosure, and FIG. 6 is a cutaway view along line A1-A2 shown in FIG. 5. The display panel further includes the ink layer 11 located in the bezel region 10 and at least partially located on a side of the cover plate 2 facing the display substrate 1. The ink layer 11 is configured to block a peripheral circuit in the bezel region 10, thereby preventing the peripheral circuit from being visible to a human eye due to reflected light. In a setting method, as shown in FIG. 6, the ink layer 11 can be further disposed on a side of the sidewall 8 of the cover plate 2 to further block light on a side surface of the cover plate 2, thereby preventing stray light from entering the display panel and reducing reflectivity. The second coating 4 overlaps with the ink layer 11.

In the above setting method, the second coating 4 is partially located in the bezel region 10. The second coating 4 can suppress inward transmission of a frictional electrostatic charge in the bezel region 10, in order to provide electrostatic protection for the peripheral circuit (such as a shift register circuit) in the bezel region 10, avoid affecting an electrical characteristic of an electronic device in the peripheral circuit, and ensure working reliability of the peripheral circuit.

Further, still referring to FIG. 6, the second coating 4 includes a first sub-coating 12. An overlapping part between the first sub-coating 12 and the ink layer 11 is located between the ink layer 11 and the cover plate 2. That is, in a process of manufacturing the display panel, the first sub-coating 12 is first formed on a side of the cover plate 2, and then the ink layer 11 is formed.

The ink layer 11 is only located in the bezel region 10 of the display panel, exposing the display region 9 of the display panel. Therefore, when the overlapping part between the first sub-coating 12 and the ink layer 11 is located between the ink layer 11 and the cover plate 2, when the first sub-coating 12 is formed, the first sub-coating 12 is not affected by the ink layer 11 and has a segment difference. The first sub-coating 12 has a flat surface and higher stability.

In addition/alternatively, as shown in FIG. 7 that is another cutaway view along line A1-A2 shown in FIG. 5, the second coating 4 includes a second sub-coating 13, and an overlapping part between the second sub-coating 13 and the ink layer 11 is located on a side of the ink layer 11 away from the cover plate 2. That is, in the process of manufacturing the display panel, the ink layer 11 is first formed on a side of the cover plate 2, and then the second sub-coating 13 is formed.

When the overlapping part between the second sub-coating 13 and the ink layer 11 is located at the side of the ink layer 11 away from the cover plate 2, the second sub-coating 13 can wrap the ink layer 11. After entering the ink layer 11, an electrostatic charge is blocked by the second sub-coating 13 and cannot be further transmitted to the interior of the display panel. This can also protect against the electrostatic charge that enters the ink layer 11 through the side surface of the display panel.

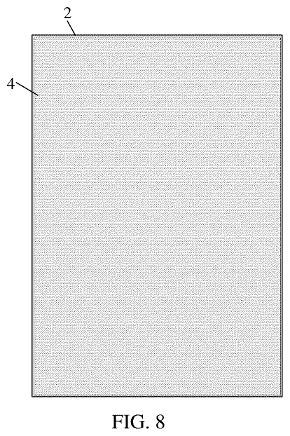

In a feasible implementation, as shown in FIG. 8 that is a top view of the cover plate 2 and the second coating 4 according to an embodiment of the present disclosure, the second coating 4 includes a light-transmitting conductive material, for example, may include a ceramic material and other high-resistance materials. In the thickness direction of the display panel, the second coating 4 covers the cover plate 2.

The second coating 4 of this structure is transparent and can cover the entire cover plate 2 without affecting normal light output of the display panel. The second coating 4 can effectively suppress the inward transmission of the frictional electrostatic charge at all locations, and has a better electrostatic protection capability.

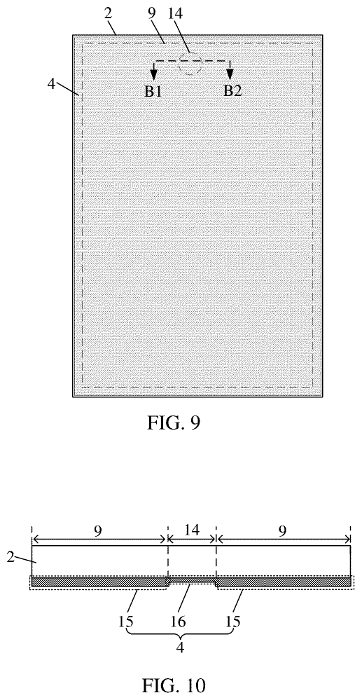

When the second coating 4 includes the light-transmitting conductive material, in a feasible implementation, as shown in FIG. 9 and FIG. 10, the display panel includes a display region 9 and a through-hole region 14, and the second coating 4 includes a first sub-portion 15 and a second sub-portion 16. FIG. 9 is another top view of the cover plate 2 and the second coating 4 according to an embodiment of the present disclosure, and FIG. 10 is a cutaway view along line B1-B2 shown in FIG. 9. The first sub-portion 15 is located in the display region 9, the second sub-portion 16 is located in the through-hole region 14, and a film thickness of the second sub-portion 16 is smaller than a film thickness of the first sub-portion 15.

The display panel generally has no film layer stacked in the through-hole region 14. Therefore, the electrostatic charge inside the cover plate is more likely to be transmitted from a sidewall of a film layer in the through-hole region 14 to an interior of the film layer. Therefore, in the embodiments of the present disclosure, the second coating 4 covers the through-hole region 14 and the film thickness of the second sub-portion 16 located in the through-hole region 14 in the second coating 4 is further reduced. In this way, surface resistance of the second sub-portion 16 can be further increased by reducing a thickness of the second sub-portion 16, so as to suppress transmission of the electrostatic charge to a greater extent in the through-hole region 14. In addition, the second sub-portion 16 is relatively thin, which can also prevent the second coating 4 from significantly affecting transmittance of the through-hole region 14.

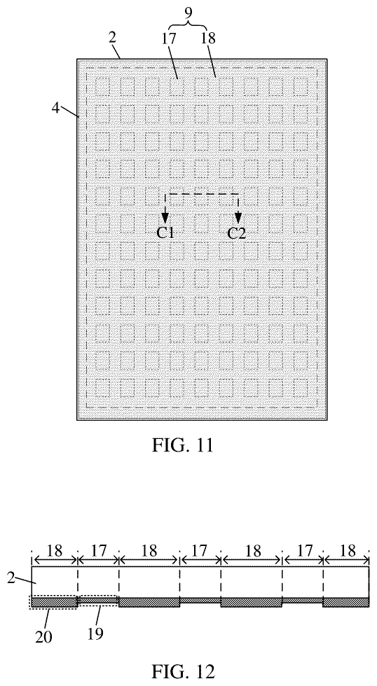

When the second coating 4 includes the light-transmitting conductive material, in a feasible implementation, as shown in FIG. 11 and FIG. 12, the display panel includes a display region 9 that includes a sub-pixel opening region 17 and a non-opening region 18, and the second coating 4 includes a third sub-portion 19 and a fourth sub-portion 20. FIG. 11 is still another top view of the cover plate 2 and the second coating 4 according to an embodiment of the present disclosure, and FIG. 12 is a cutaway view along line C1-C2 shown in FIG. 11. The third sub-portion 19 is located in the sub-pixel opening region 17, the fourth sub-portion 20 is located in the non-opening region 18, and a film thickness of the third sub-portion 19 is smaller than a film thickness of the fourth sub-portion 20.

The sub-pixel opening region 17 is a light exit region of a sub-pixel. In an organic light-emitting diode (OLED) display panel, the sub-pixel opening region 17 can be limited by an opening of a pixel definition layer, and in a liquid crystal display panel, the sub-pixel opening region 17 can be limited by an opening of a black matrix.

In the above structure, in addition to effectively suppressing transmission of an electrostatic charge in the sub-pixel opening region 17 and the non-opening region 18, the second coating 4 can also reduce an impact of the second coating 4 on light output of the sub-pixel in the sub-pixel opening region 17. This ensures that the sub-pixel opening region 17 has a high light output rate and a light-emitting element has high light luminance.

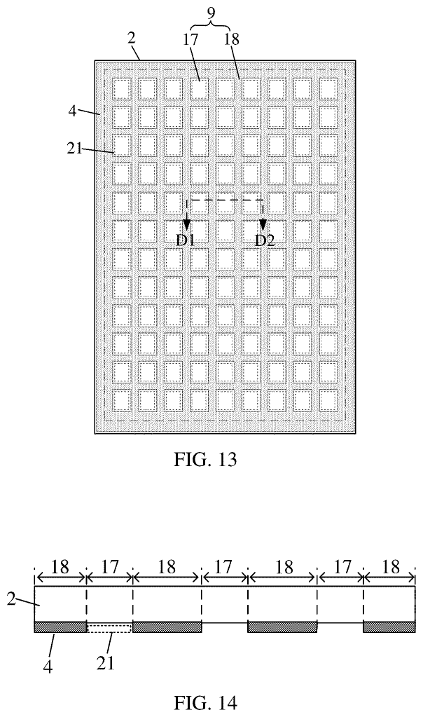

In a feasible implementation, as shown in FIG. 13 and FIG. 14, the display panel includes a display region 9 that includes a sub-pixel opening region 17 and a non-opening region 18, and the second coating 4 has a hollow 21 that exposes the sub-pixel opening region 17. FIG. 13 is yet another top view of the cover plate 2 and the second coating 4 according to an embodiment of the present disclosure, and FIG. 14 is a cutaway view along line D1-D2 shown in FIG. 13.

In the second coating 4 of this structure, the hollow 21 can be disposed to expose the sub-pixel opening region 17. In this case, the second coating 4 no longer overlaps with the sub-pixel opening region 17, and there is no need to consider whether a material of the second coating 4 is transparent. This can increase flexibility of material selection for the second coating 4. For example, the second coating 4 may be made of a material that is not transparent but has higher resistance, to enhance an electrostatic transmission blocking capability of the second coating 4.

Further, the second coating 4 may include an opaque conductive material, for example, a metal material. The opaque conductive material can be selected from a wide range, for example, from a plurality of metal materials with different resistivity, to optimize a setting of surface resistance of the opaque conductive material.

In a feasible implementation, as shown in FIG. 15 that is still another schematic cross-sectional view of the display panel according to an embodiment of the present disclosure, the display panel further includes a filter 22 located between the display substrate 1 and the cover plate 2. The filter 22 includes a color resistor 23. The color resistor 23 is at least partially located within the hollow 21 of the second coating 4, and the second coating 4 is reused as a black matrix 24.

More specifically, still referring to FIG. 15, in a setting method, the display substrate 1 includes a substrate 25, an array layer 26, a light-emitting element 27, and a packaging layer 28. In the thickness direction of the display panel, the color resistor 23 overlaps with the light-emitting element 27, and the overlapping color resistor 23 and light-emitting element 27 have a same color. The color resistor 23 is configured to emit light with a same color as the color resistor 23 and filter out light with a different color from the color resistor 23. This type of display panel uses the filter 22 to replace the polarizer to achieve a filtering effect, which is also known as a depolarization technology. In a traditional design of the filter 22, the filter 22 includes the color resistor 23 and the black matrix. However, in the embodiments of the present disclosure, when the second coating 4 is made of an opaque material, the second coating 4 can be reused as the black matrix 24. In this case, the second coating 4 has a function of suppressing electrostatic transmission and a shading function. In this way, an original black matrix structure in the filter 22 is not required, simplifying a structure of this type of display panel, and reducing a production cost.

However, it should be noted that in addition to be applied to the above display panel that uses the depolarization technology, the solutions provided in the embodiments of the present disclosure can also be applied to other types of display panels.

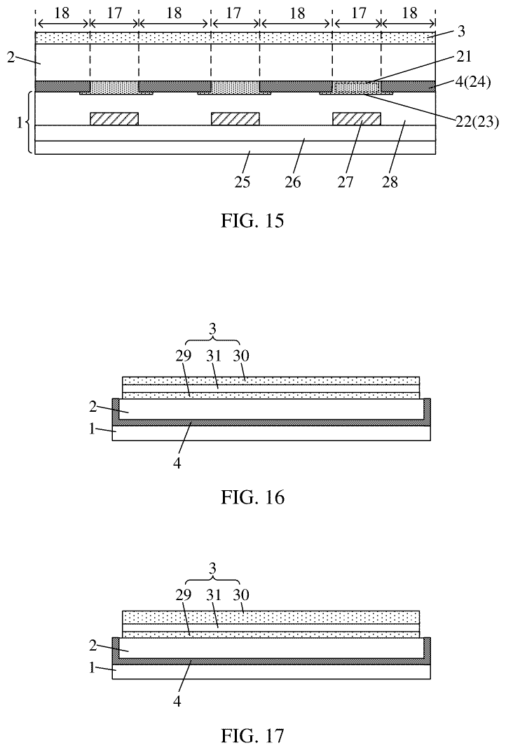

In a feasible implementation, as shown in FIG. 16 that is still another schematic cross-sectional view of the display panel according to an embodiment of the present disclosure, the first coating 3 includes a third sub-coating 29 and a fourth sub-coating 30, and a first dielectric layer 31 is further located between the third sub-coating 29 and the fourth sub-coating 30. The third sub-coating 29 and the fourth sub-coating 30 each may include a low-resistance material such as a metal oxide. The first dielectric layer 31 may include a material like silicon dioxide.

As mentioned earlier, the surface resistance of the first coating 3 is low, and can be generally reduced by increasing a thickness of the first coating 3. If the first coating 3 is designed with only one layer, the first coating 3 is thick, and it may be difficult to accurately control thicknesses of the first coating 3 at different locations. As a result, film thicknesses of the first coating 3 at the different locations are different, causing inconsistent dissipation of the electrostatic charge by the first coating 3 at the different locations.

In the embodiments of the present disclosure, the first coating 3 is disposed to include at least the third sub-coating and the fourth sub-coating 30. This makes a difference between total thicknesses of the two sub-coatings at the different locations smaller. For example, a location at which the third sub-coating 29 is thin may correspond exactly to a location at which the fourth sub-coating 30 is thick, thereby keeping a total thickness of the third sub-coating 29 and the fourth sub-coatings 30 at the location consistent with that at another location. This setting method can improve a consistent resistance value of the first coating 3 at the different positions, thereby achieving consistent electrostatic charge dissipation of the first coating 3 at the different locations.

Further, the fourth sub-coating 30 is located a side of the third sub-coating 29 away from the display substrate 1, and surface resistance of the fourth sub-coating 30 is smaller than surface resistance of the third sub-coating 29. In a setting method, as shown in FIG. 17 that is still another schematic cross-sectional view of the display panel according to an embodiment of the present disclosure, when a same material is used for the third sub-coating 29 and the fourth sub-coating 30, a larger film thickness may be set for the fourth sub-coating 30 to reduce the surface resistance of the fourth sub-coating 30.

The fourth sub-coating 30 is closer to a light exit side of the display panel. Therefore, lower surface resistance is set for the fourth sub-coating 30 to quickly dissipate the frictional electrostatic charge on the light exit side of the display panel, thereby greatly reducing electrostatic charges that enter the cover plate 2 and then are transmitted inward.

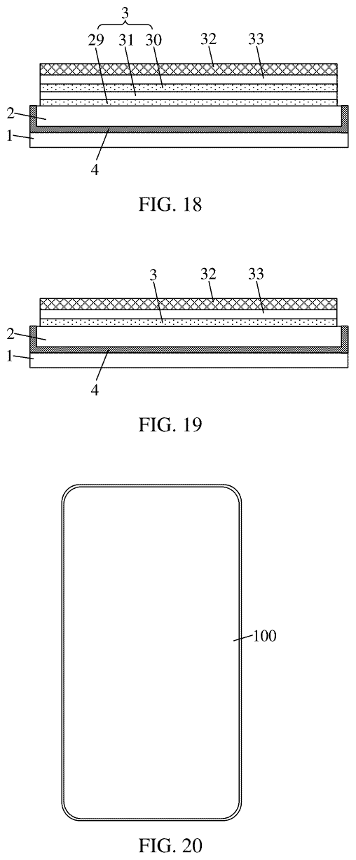

In a feasible implementation, as shown in FIG. 18 and FIG. 19, the display panel further includes an anti-fingerprint layer 32 located on a side of the first coating 3 away from the cover plate 2. FIG. 18 is still another schematic cross-sectional view of the display panel according to an embodiment of the present disclosure, and FIG. 19 is still another cross-sectional view of the display panel according to an embodiment of the present disclosure. The anti-fingerprint layer 32 may be an anti-fingerprint coating. As a fluorinated coating, the anti-fingerprint layer 32 has good waterproof and oil-proof effects, and can enhance smoothness and touch feeling of the display panel, and prevent a user from leaving a fingerprint mark on the screen surface to make the display panel aesthetically pleasing. A second dielectric layer 33 is further located between the anti-fingerprint layer 32 and the first coating 3, and may be made of a material like silicon dioxide.

On one hand, the second dielectric layer 33 can protect the first coating 3, improve oxidation resistance and corrosion resistance of the first coating 3, and provide reliable electrostatic protection for the first coating 3. On the other hand, the second dielectric layer 33 can also serve as a base layer of the anti-fingerprint layer 32, such that the anti-fingerprint layer 32 is formed above the second dielectric layer 33.

In a feasible implementation, the surface resistance of the first coating 3 is R1, and the surface resistance of the second coating 4 is R2. In order to ensure that the first coating 3 has a good capability for preventing accumulation of the electrostatic electricity and the second coating 4 has a good capability for suppressing the transmission of the electrostatic charge, R1 and R2 may be set as follows: 10⁷Ω<R1<10¹¹Ω, and R2>10¹³Ω.

Based on the same inventive concept, the embodiments of the present disclosure further provide a display apparatus. FIG. 20 is a schematic structural diagram of a display apparatus according to an embodiment of the present disclosure. As shown in FIG. 20, the display apparatus includes the foregoing display panel 100. A specific structure of the display panel 100 has been described in detail in the foregoing embodiments. Details are not described herein again. Certainly, the display apparatus shown in FIG. 20 is for schematic description only. The display apparatus may be any electronic device with a display function, such as a mobile phone, a tablet computer, a notebook computer, an ebook, or a television.

The above descriptions are merely preferred embodiments of the present disclosure, and are not intended to limit the present disclosure. Any modifications, equivalent replacements, improvements, and the like made within the spirit and principle of the present disclosure shall fall within the protection scope of the present disclosure.

It should be noted that the above embodiments are merely intended to describe the technical solutions of the present disclosure, rather than to limit the present disclosure. Although the present disclosure is described in detail with reference to the above embodiments, persons of ordinary skill in the art should understand that they may still make modifications to the technical solutions described in the above embodiments or make equivalent replacements to some or all technical features thereof, without departing from the essence of the technical solutions in the embodiments of the present disclosure.

What is claimed is:

1. A display panel, comprising:
a display substrate;
a cover plate located on a side of the display substrate facing a light exit surface of the display panel;
a first coating located on a side of the cover plate away from the display substrate; and
a second coating at least partially located on a side of the cover plate adjacent to the display substrate, wherein
a surface resistance of the second coating is greater than a surface resistance of the first coating.

2. The display panel according to claim 1, wherein
the cover plate has a bottom surface adjacent to the display substrate and a sidewall intersecting the bottom surface, and
the second coating is located on the bottom surface and the sidewall.

3. The display panel according to claim 1, further comprising:
a display region and a bezel region; and
an ink layer located in the bezel region, wherein
the ink layer is at least partially located on a side of the cover plate facing the display substrate, and the second coating overlaps the ink layer.

4. The display panel according to claim 3, wherein
the second coating comprises a first sub-coating, and an overlapping part between the first sub-coating and the ink layer is located between the ink layer and the cover plate.

5. The display panel according to claim 3, wherein
the second coating comprises a second sub-coating, and an overlapping part between the second sub-coating and the ink layer is located on a side of the ink layer away from the cover plate.

6. The display panel according to claim 1, wherein
the second coating comprises a light-transmitting conductive material and covers the cover plate in a thickness direction of the display panel.

7. The display panel according to claim 6, comprising a display region and a through-hole region, wherein,
the second coating comprises a first sub-portion located in the display region and a second sub-portion located in the through-hole region, and
a film thickness of the second sub-portion is smaller than a film thickness of the first sub-portion.

8. The display panel according to claim 6, comprising a display region that comprises a sub-pixel opening region and a non-opening region, wherein
the second coating comprises a third sub-portion located in the sub-pixel opening region and a fourth sub-portion located in the non-opening region, and a film thickness of the third sub-portion is smaller than a film thickness of the fourth sub-portion.

9. The display panel according to claim 1, having a display region that comprises a sub-pixel opening region and a non-opening region, wherein
the second coating has a hollow that exposes the sub-pixel opening region.

10. The display panel according to claim 9, wherein the second coating comprises an opaque conductive material.

11. The display panel according to claim 10, further comprising a filter located between the display substrate and the cover plate, wherein the filter comprises a color resistor; and
the color resistor is at least partially located within the hollow of the second coating, and the second coating is reused as a black matrix.

12. The display panel according to claim 1, wherein,
the first coating comprises a third sub-coating and a fourth sub-coating, and
a first dielectric layer is further located between the third sub-coating and the fourth sub-coating.

13. The display panel according to claim 12, wherein
the fourth sub-coating is located on a side of the third sub-coating away from the display substrate, and a surface resistance of the fourth sub-coating is smaller than a surface resistance of the third sub-coating.

14. The display panel according to claim 1, further comprising an anti-fingerprint layer located on a side of the first coating away from the cover plate, wherein
a second dielectric layer is further located between the anti-fingerprint layer and the first coating.

15. The display panel according to claim 1, wherein
the surface resistance of the first coating is represented as R1, and the surface resistance of the second coating is represented as R2, where 10⁷Ω<R1<10¹¹Ω, and R2>10¹³Ω.

16. A display apparatus, comprising a display panel wherein the display panel, comprises a display substrate;
a cover plate located on a side of the display substrate facing a light exit surface of the display panel;
a first coating located on a side of the cover plate away from the display substrate; and
a second coating at least partially located on a side of the cover plate adjacent to the display substrate, wherein
a surface resistance of the second coating is greater than a surface resistance of the first coating.
